(19) United States
(12) Patent Application Publication
(10) Pub. No.: US 2018/0119284 A1
(43) Pub. Date: May 3, 2018

(54) MAINTENANCE DEVICE AND METHOD OF USING THE SAME

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Haitao WANG, Beijing (CN); Niu TIAN, Beijing (CN); Wenyuan SUN, Beijing (CN); Song GAO, Beijing (CN)

(21) Appl. No.: 15/503,877

(22) PCT Filed: Sep. 13, 2016
(86) PCT No.: PCT/CN2016/098878

§ 371 Date: Feb. 14, 2017

(30) Foreign Application Priority Data
Jan. 4, 2016 (CN) 201610004251.6

(51) Int. Cl. C23C 16/52; C23C 16/455; C23C 16/44

(52) U.S. Cl. CPC C23C 16/52; C23C 16/4401; C23C 16/455

(57) ABSTRACT

An apparatus includes a powder storage tank (21) and a gas chamber (14), the powder storage tank (21) being provided with an outlet duct (23) in communication with the gas chamber (14). The apparatus further includes a monitoring device (24), a first switch (25) and a second switch (26). The monitoring device (24) is provided between the powder storage tank (21) and the gas chamber (14) while communicating with the outlet duct, and configured to monitor the powder content per unit volume in the outlet duct when the gas path between the monitoring device and the gas chamber is in the close state. The first switch (25) is provided between the monitoring device (24) and the outlet duct (23), and the second switch (26) is provided between the monitoring device (24) and the gas chamber (14). A method of using the apparatus is also provided.

### BACKGROUND

Embodiments of the present disclosure relate to a maintenance device and the method of using the same.

Chemical Vapor Deposition (CVD) maintenance facilities are the major maintenance facilities in the array section in the field of the thin film transistor liquid crystal display (TFT-LCD) panel, which are used to inspect, grade and repair line defects and point defects on the array substrate. Its principle is to deposit tungsten powder through the thermal effect and light effect of laser, to connect the conductive metal wires so as to repair defects, such as open defects. The CVD maintenance facilities may also cut the metal residue of the conductive film on the substrate, and tungsten powder could be deposited thereon after the cutting to bridge the conductive metal wires, in this way, defects, such as Remain defects, can be repaired and the product yield can be improved.

### SUMMARY

Embodiments of the present disclosure provide an apparatus and a method of using the same for reducing the probability of failure on the substrate line maintenance and improving the quality of the substrate.

According to at least one embodiments of the present disclosure, an apparatus is provided, including: a powder storage tank; a gas chamber, the powder storage tank being provided with an outlet duct connected with the gas chamber; a monitoring device; a first switch; and a second switch. The first switch is provided between the monitoring device and the outlet duct, and the second switch is provided between the monitoring device and the gas chamber. The monitoring device is provided between the powder storage tank and the gas chamber and communicates with the outlet duct, and is configured to monitor powder content per unit volume in the outlet duct when the second switch is turned off and the first switch is turned on.

For example the monitoring device includes a powder collecting device, a spring and a pressure sensor. The powder collecting device being configured to collect the gaseous matter in the outlet duct and solidify the collected gaseous matter into solid matter when the first switch is turned on and the second switch is turned off. The pressure sensor being connected with the powder collecting device through the spring, and configured to obtain a value of time-varying pressure converted to a digital signals by detecting the pressure of the spring when the gaseous matter is solidified into solid matter, and to obtain the powder content per unit volume in the outlet duct according to pre-established correspondence between the pressure and the powder content per unit volume.

For example, the powder collecting device includes a hollow cylindrical collector configured to collect solid matters and a temperature regulating device coupled with the hollow cylindrical collector. The temperature regulating device is configured to cool down the hollow cylindrical collector when the first switch is turned on and the second switch is turned off, to allow the gaseous matter to be solidified into solid matter.

For example, the temperature regulating device is further configured to warm up the hollow cylindrical collector when the first switch is turned off and the second switch is turned on, to allow the solid matter collected in the hollow cylindrical collector to be sublimated to gaseous matter.

For example, the temperature regulating device is a container filled with water. When the first switch is turned on and the second switch is turned off, the temperature of the water is set to be a first preset temperature at which the gaseous matter is solidified into solid matter. When the first switch is turned off and the second switch is turned on, the temperature of the water is set to be a second preset temperature at which the solid matter is sublimated to gaseous matter.

For example, the monitoring device is provided with a recovery pump therein which is configured to clean the monitoring device.

For example, the monitoring device includes a cooling device, a sampling room and a particle concentration detector.

For example, the cooling device is disposed proximate to the sampling room and configured to solidify the gaseous matter in the outlet duct into solid matter when the first switch is turned on and the second switch is turned off. The sampling room is configured to collect the solid matter. The particle concentration detector is provided within the sampling room and configured to detect the concentration of the solid matter.

For example, the bottom end of the powder storage tank is implemented as a movable structure configured to adjust the volume of the powder storage tank.

For example, the apparatus further includes an alarm regulating device coupled with the powder storage tank and the monitoring device, the alarm regulating device being configured to receive the powder content per unit volume in the outlet duct fed back by the monitoring device, compare the value of the powder content per unit volume with a preset range, when the value of the powder content per unit volume exceeds the preset range, issue an alarm and control movement of the movable structure until the alarm is eliminated.

For example, the movable structure is a piston.

For example, the outlet of the outlet duct connected with the powder storage tank has a trapezoidal cross-sectional shape.

For example, the powder storage tank is provided with an intake duct configured to introduce an inert gas. The inlet of the intake duct connected with the powder storage tank has a trapezoidal cross-sectional shape.

For example, the first switch is an electromagnetic valve; and the second switch is an electromagnetic valve.

According to at least one embodiments of the present disclosure, a method of using the apparatus is provided, including: controlling a second switch between the monitoring device and the gas chamber to turn off, and controlling the first switch between the monitoring device and the outlet duct to turn on, to monitor the powder content per unit volume in the outlet duct; and controlling the second switch between the monitoring device and the gas chamber to turn on and controlling the first switch between the monitoring device and the outlet duct to turn off to output the gas for depositing a thin film.

For example, the monitoring device includes a powder collecting device, a spring and a pressure sensor, the pressure sensor being connected with the powder collecting device through the spring. The monitoring of the powder content per unit volume in the outlet duct includes collecting the gaseous matter in the outlet duct by the powder collecting device and solidifying the collected gaseous matter into solid matter; obtaining a value of time-varying pressure converted to a digital signals by detecting the pressure of the spring, and obtaining the powder content per unit volume in the outlet duct according to the pre-established correspondence between the pressure and the powder content per unit volume by the pressure sensor.

For example, the bottom end of the powder storage tank is implemented as a movable structure configured to adjust the volume of the powder storage tank. The method further includes coupling an alarm regulating device with the powder storage tank and the monitoring device, and after monitoring out the powder content per unit volume in the outlet duct, the alarm regulating device receives the powder content per unit volume in the outlet duct fed back by the monitoring device, compare the value of the powder content per unit volume with a preset range, and when the value of the powder content per unit volume exceeds the preset range, issue an alarm and control the movement of the movable structure until the alarm is eliminated.

### BRIEF DESCRIPTION OF THE DRAWINGS

Embodiments of the present disclosure will be described in detail hereinafter in conjunction with accompanying drawings to allow one of ordinary skill in the art to understand the present disclosure more clearly, in which:

FIG. 1 is a structural schematic view of a CVD maintenance facility;

FIG. 2 is a structural schematic view of an apparatus according to an embodiment of the present disclosure;

FIG. 3 is a structural schematic view of the monitoring device according to the first embodiment of the present disclosure;

FIGS. 4(a) and 4(b) are structural schematic views of the powder collecting device according to the first embodiment of the present disclosure;

FIG. 5 is a structural schematic view of the monitoring device according to the second embodiment of the present disclosure;

FIG. 6 is a partial structural schematic view of the apparatus according to another embodiment of the present disclosure;

FIG. 7 is a flowchart of a method of using the apparatus according to an embodiment of the present disclosure.

### DETAILED DESCRIPTION

Embodiments of the present disclosure provide an apparatus and a method of using the same for reducing the probability of failure on the substrate line maintenance and improving the quality of the substrate.

The technical solutions of the embodiments will be described in a clearly and fully understandable way in connection with the drawings related to the embodiments of the disclosure. It is apparent that the described embodiments are just a part but not all of the embodiments of the disclosure. Based on the described embodiments herein, one of ordinary skill in the art can obtain other embodiment(s), without any inventive work, which should be within the scope of the disclosure.

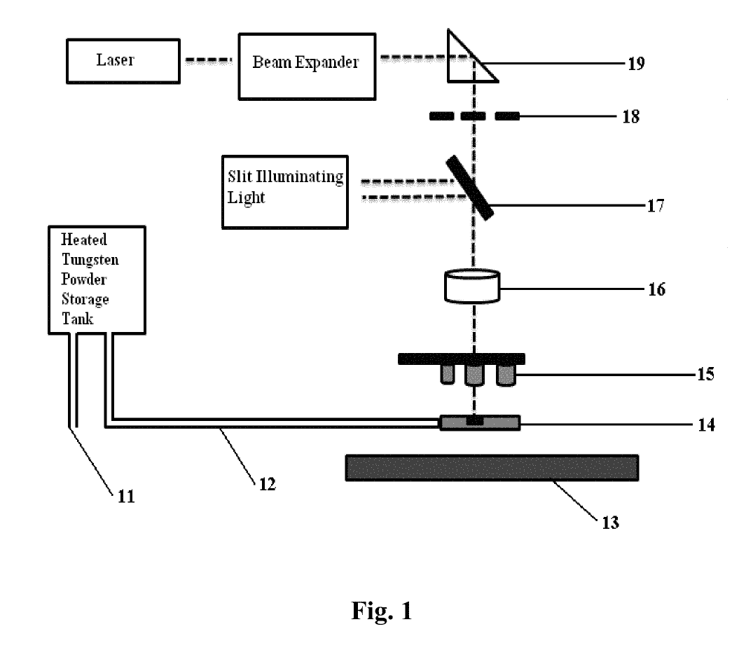

As shown in FIG. 1, the CVD maintenance facility includes a heated tungsten powder storage tank, an intake duct 11 of argon (Ar) connected to the tungsten powder storage tank, and a heating pipe 12, a gas chamber 14 connected to the heating pipe 12, an objective lens 15, a barrel lens 16, a separator 17, a wavelength selector 18 and a bending prism 19, the CVD maintenance facility could inspect, grade and repair line defects and point defects of an array substrate 13.

The inventors notice that when a CVD maintenance facility is used to repair an array substrate, there are problems as follows:

The inlet and outlet of the tungsten powder storage tank in the CVD maintenance facility are cylindrical; the inlet of a cylindrical design results in an single blowing direction and a larger airflow of some regions, which would lead to accumulation of the tungsten powder at the outlet, and moreover, such a design disables some regions to be blown, a saturated tungsten vapor is formed and resulting in tungsten powder crystallization and accumulation; all of the above will reduce the content of the tungsten powder in the gas chamber and allow the deposited tungsten powder film to become thinner. In an instance that no backlight penetrates, the status of maintenance cannot be aware. That is to say, if the backlight could run through the film after such a film is deposited, it indicates that the maintenance is failure; if the backlight doesn't run through this film, it remains to require that the thickness of this film cannot be too thin in the case of no light penetration, whereas in this instance, due to the thinning of the deposited tungsten powder film, the maintenance failure will be more gradually.

During the use of the tungsten powder, only the running time of the apparatus is recorded as the service time of the tungsten powder, however, the tungsten powder is not in use for most of the time in the operation of the apparatus; furthermore, the tungsten powder consumption for each of the apparatuses is also different, so the record is not accurate. Since the tungsten powder is replaced in accordance with the running time, the use rate of the tungsten powder is depressed enormously, resulting in the wastage of the tungsten powder.

In the process of equipment maintenance or abnormal power down, the tungsten powder pipes or other locations are blocked, and at the end of the use of tungsten powder, the content of tungsten powder in the reactant gas will be reduced and cannot be monitored. Moreover, in the tungsten powder storage tank of current design, even if the deposited film is found to be remarkably thin and light-transmissive, the only measure employed is to replace the tungsten powder, which is simplex and cannot sufficiently identify the status of tungsten powder, resulting in the wastage of tungsten powder, and the activation of the apparatus is affected.

When this kind of CVD maintenance facility is used to repair an array substrate, in the case of abnormal use of tungsten powder, such as exhaustion of use, pipe clogging, crystallization of tungsten powder or the like, the tungsten powder cannot be monitored in time, causing the quality of the deposited tungsten powder film to be declined and the rate of maintenance failure to be increased. Moreover, when obvious abnormity occurs in the tungsten powder, it is impossible to adjust it effectively, but only to replace the tungsten powder, this method is simplex and the activation of the apparatus is affected, as well as production capacity is impacted.

A detailed introduction will be made to the maintenance apparatus provided by exemplary embodiments of the present disclosure, which is configured to repair the substrate circuit, but embodiments of the present disclosure are not limited thereto.

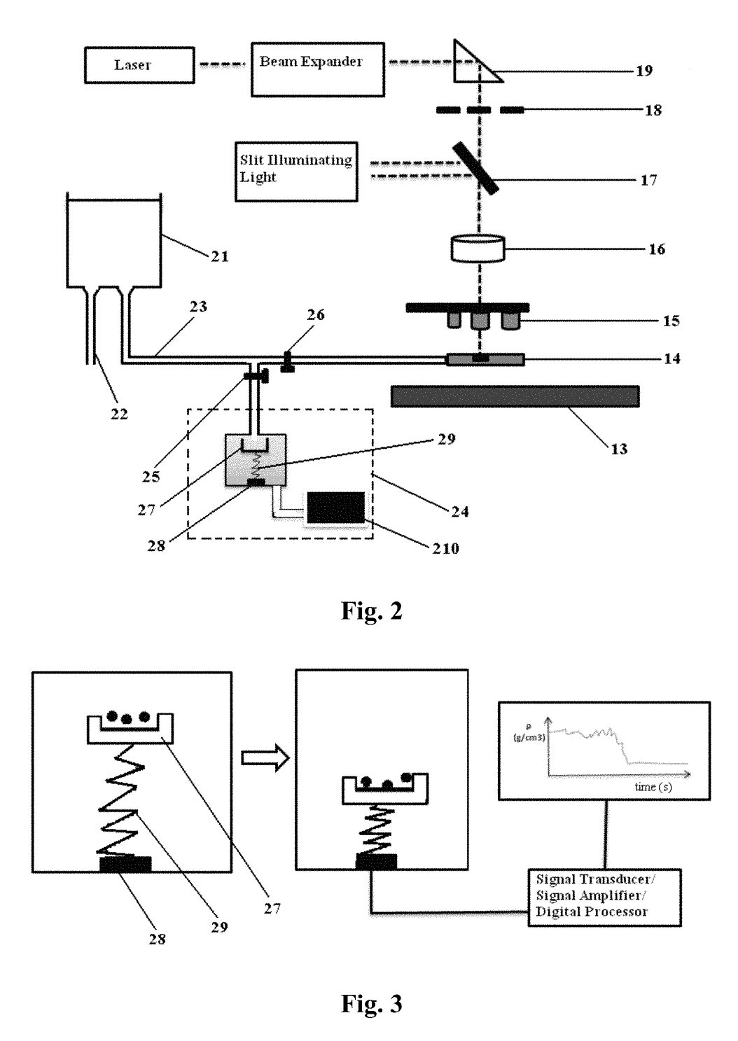

As shown in FIG. 2, an exemplary embodiment of the present disclosure provides an apparatus including a powder storage tank 21 and a gas chamber 14. The powder storage tank 21 is provided with an intake duct 22 and an outlet duct 23. The intake duct 22 is configured to introduce an inert gas. The outlet duct 23 communicates with the gas chamber 14. The apparatus of the exemplary embodiment of the present disclosure also includes a monitoring device 24, a first switch 25 and a second switch 26.

The first switch 25 is provided between the monitoring device 24 and the outlet duct 23, and the second switch 26 is provided between the monitoring device 24 and the gas chamber 14. For example, the first switch 25 of the exemplary embodiment of the present disclosure is an electromagnetic valve, and the second switch 26 is an electromagnetic valve. When in operation, the electromagnetic valves can be controlled to turn on or turn off by power on and off, so as to remotely control it automatically. But embodiments of the present disclosure are not limited thereto.

The monitoring device 24 is provided between the powder storage tank 21 and the gas chamber 14 and communicates with the outlet duct 23. The Monitoring device 24 is configured to, when the second switch 26 is turned off and the first switch 25 is turned on, that is, when the gas path between the monitoring device 24 and the gas chamber 14 is in the close state, monitor the powder content per unit volume in the outlet duct 23.

For example, as shown in FIG. 2, the inlet of the intake duct 22 of the exemplary embodiment of the present disclosure connected to the powder storage tank 21 has a trapezoidal cross-sectional shape; and the outlet of the outlet duct 23 connected to the powder storage tank 21 has a trapezoidal cross-sectional shape, but embodiments of the present disclosure are not limited thereto.

The powder in the exemplary embodiment of the present disclosure is tungsten powder, for example. Compared with the inlet and outlet of the cylindrical tungsten powder storage tank, the inlet and outlet of the tungsten powder storage tank is designed to be a trapezoidal configuration in the exemplary embodiment of the present disclosure, which could enlarge the bore size so that the inlet has diversified airflow directions, and so that problems, such as crystallization and clogging of tungsten powder, are unlikely to occur at the outlet.

The monitoring device of the exemplary embodiment of the present disclosure employs two different arrangements, which are described below in conjunction with the drawings.

### Embodiment One

As shown in FIG. 2, the monitoring device 24 of the exemplary embodiment of the present disclosure includes a powder collecting device 27, a spring 29 and a pressure sensor 28.

The powder collecting device 27 is configured to, when the first switch 25 is turned on and the second switch 26 is turned off, collect the gaseous matter in the outlet duct 23 and solidify the collected gaseous matter into a solid matter.

The pressure sensor 28 is connected with the powder collecting device 27 through the spring 29, and configured to obtain a value of time-varying pressure converted to a digital signals by detecting the pressure of the spring 29 when the gaseous matter is solidified into solid matter, and to obtain the powder content per unit volume in the outlet duct 23 according to the pre-established correspondence between the pressure and the powder content per unit volume.

The working principle of the monitoring device for monitoring the tungsten powder content according to exemplary embodiments of the present disclosure will be described below in detail in connection with the attached drawings, for example, tungsten powder is used as the powder.

As shown in FIG. 2, when the first switch 25 is turned on and the second switch 26 is turned off, the gas in the outlet duct 23 can only enter the monitoring device 24 and cannot enter the gas chamber 14. In practice, the gas introduced into the intake duct 22 of the exemplary embodiment of the present disclosure is argon (Ar) gas, and the powder storage tank 21 is heated so that the tungsten powder stored in the powder storage tank 21 becomes gaseous tungsten powder which is blown by the Ar gas, pass through the outlet and get into the outlet duct 23. When the first switch 25 is turned on and the second switch 26 is turned off, the gaseous tungsten powder enters the monitoring device 24.

As shown in FIG. 3, when the powder collecting device 27 solidifies the collected gaseous tungsten powder into a solid tungsten powder, the spring 29 would deform under the force of the solid tungsten powder and generate a corresponding pressure, which is sensed by the pressure sensor 28, and is processed by a signal transducer, a signal amplifier and a digital processor in the pressure sensor 28 to obtain a value of time-varying pressure already converted into a digital signal, then obtain the content of gaseous tungsten powder per unit volume in the outlet duct 23 according to a pre-established correspondence between the pressure and the content of gaseous tungsten powder per unit volume.

For example, as shown in FIGS. 2 and 3, in the exemplary embodiment of the present disclosure, by controlling the time for turning on the first switch 25 and turning off the second switch 26 as well as by controlling the content of tungsten powder in the powder storage tank 21, a series of pressure changes in the powder collecting device 27 are tested, and in an instance that the Ar gas flow is constant and known, the gaseous tungsten powder content per unit volume and per unit time are calculated, and then the thickness of the corresponding deposited tungsten powder film is measured, so as to obtain an relation database of one-to-one correspondence of the corresponding pressure to the gaseous tungsten powder content per unit volume, as well as the pressure to the film thickness.

In the exemplary embodiment of the present disclosure, a favorable scope for the tungsten powder content is selected according to the relation database of the one-to-one correspondence of the pressure to the gaseous tungsten powder content per unit volume and the pressure to the film thickness, so as to monitor the use status of the tungsten powder.

In the exemplary embodiment of the present disclosure, the monitoring device is used to monitor the content and use status of tungsten powder, which, compared with the case in which the use status of tungsten powder can only be recorded by recording the running time of the apparatus and observing the light transmittance of the deposited tungsten powder film, the stability of the content of the output tungsten powder is enormously improved, and the film quality in the process of maintenance is maintained and the success rate of the maintenance is improved.

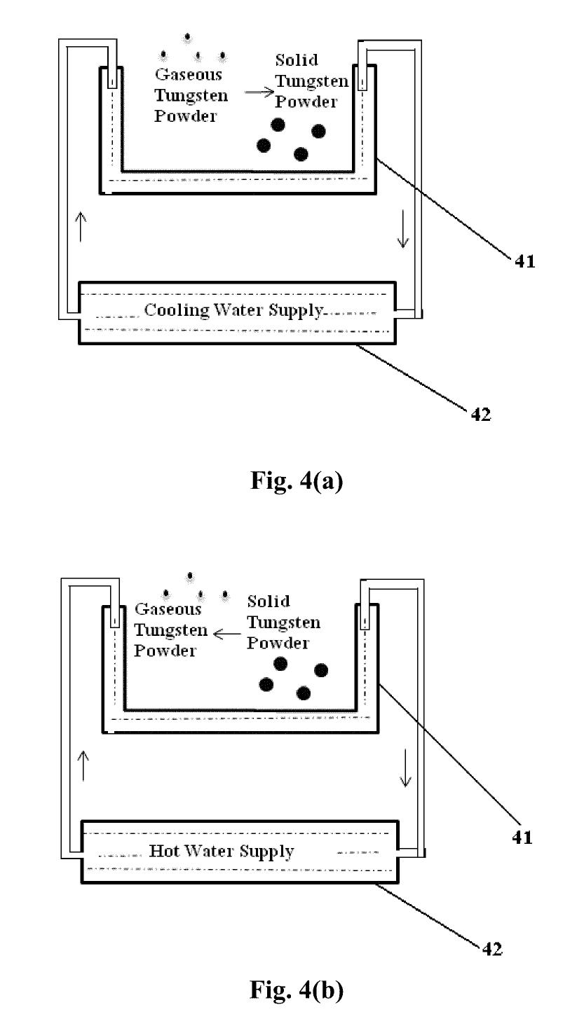

For example, as shown in FIG. 4(a) and FIG. 4(b), the powder collecting device 27 of an exemplary embodiment of the present disclosure includes a collector 41 configured to collect the solid matter and a temperature regulating device 42 connected with the collector 41. As shown in FIGS. 2 and 4(a), the temperature regulating device 42 of the exemplary embodiment of the present disclosure is configured to, when the first switch 25 is turned on and the second switch 26 is turned off, cool down the collector 41 so that the gaseous tungsten powder solidifies into a solid tungsten powder. For example, the temperature regulating device 42 is a container filled with water at a first preset temperature at which the gaseous tungsten powder can be solidified into solid tungsten powder. The first preset temperature is a temperature value set according to actual conditions. When in operation, the temperature regulating device 42 is a device capable of supplying cooling water for the collector 41.

As shown in FIGS. 2 and 4(b), the temperature regulating device 42 in the exemplary embodiment of the present disclosure is also configured to, when the first switch 25 is turned off and the second switch 26 is turned on, warm up the collector 41, so that the solid tungsten powder collected in the collector 41 sublimates to a gaseous tungsten powder. For example, the temperature regulating device 42 is a container filled with water at a second preset temperature at which the solid tungsten powder can be sublimated to gaseous tungsten powder. The second preset temperature is a temperature value set according to actual conditions. When in operation, the temperature regulating device 42 is a device capable of supplying hot water for the collector 41.

For example, as shown in FIGS. 2 and 4(b), the monitoring device 24 in the exemplary embodiment of the present disclosure is provided with a recovery pump 210 therein, and the recovery pump 210 is configured to clean the monitoring device 24. In operation, the collector 41 is firstly provided with hot water so that the solid tungsten powder in the collector 41 sublimates to gaseous tungsten powder; then the recovery pump 210 is turned on to draw out the impurities, such as tungsten powder or the like, from the entire monitoring device so as to clean the monitoring device 24.

The collector 41 is hollow cylinder-liked, for example.

### Embodiment 2

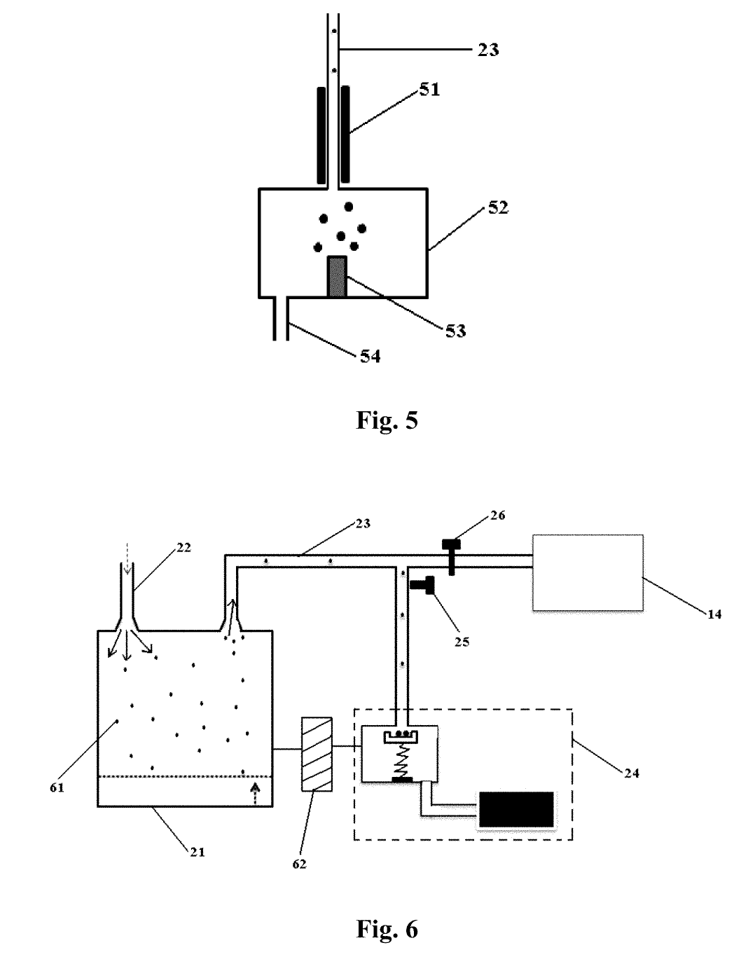

As shown in FIG. 5, the monitoring device in this exemplary embodiment of the present disclosure includes a cooling device 51, a sampling room 52 and a particle concentration detector 53;

The cooling device 51 is disposed proximate to the sampling room 52 and configured to, when the first switch is turned on and the second switch is turned off, solidify the gaseous matter in the outlet duct 23 into solid matter.

The sampling room 52 is configured to collect solid matters.

The particle concentration detector 53 is provided in the sampling room 52 and configured to detect the concentration of the solid matter.

The exemplary embodiment of the present disclosure is described taking tungsten powder as the powder as an example, the cooling device 51 which is provided outside of the outlet duct 23 and proximate to the sampling room 52, for example, is used to solidify the gaseous tungsten powder in the outlet duct 23 into solid tungsten powder. The solid tungsten powder is collected into the sampling room 52, and the particle concentration detector 53, which is provided in the sampling room 52, is used to detect the concentration of the solid tungsten powder.

The particle concentration detector of this exemplary embodiment of the present disclosure utilizes beta ray absorption principle to automatically detect the particle concentration of the cooled tungsten powder and estimate the gaseous tungsten powder content in the outlet duct, so as to monitor it. When the gaseous tungsten powder content is monitored in this way, the data acquisition is simpler and its sensitivity is higher, moreover, the sampling room 52 in FIG. 5 is also provided with an air outlet 54 at one end thereof. The air outlet 54 is configured to discharge the disused tungsten powder in the sampling room 52 so as to clean the sampling room.

As shown in FIG. 6, the bottom end of the powder storage tank 21 of the exemplary embodiment of the present disclosure is designed to be a movable structure, which is configured to adjust the volume of the powder storage tank 21. For example, the movable structure is a piston, and the upward movement of which could decrease the volume of the powder storage tank 21, as indicated by the dotted arrow at the lower portion of the powder storage tank 21, but the embodiments of the present disclosure are not limited thereto.

The apparatus of an exemplary embodiment of the present disclosure also includes an alarm regulating device 62 coupled with the powder storage tank 21 and the monitoring device 24. The alarm regulating device 62 is configured to receive the powder content per unit volume in the outlet duct 23 fed back by the monitoring device 24, and compare the value of the powder content per unit volume with a preset range. When the powder content per unit volume exceeds the preset range, the alarm regulating device 62 issues an alert and controls the movable structure to move until the alarm is eliminated.

The exemplary embodiment of the present disclosure is designed to allow the bottom end of the powder storage tank to be a movable structure, so that a powder storage tank having a movable bottom end is provided. In an instance that powder abnormity occurs in the powder storage tank, it is possible to adjust the volume of the powder storage tank to keep the powder content per unit volume unchanged. In this way, the quality of the repaired film is maintained and the success rate of maintenance is increased.

Description will be made to the exemplary embodiment of the present disclosure in connection with the FIG. 6, while taking tungsten powder as the powder and taking the monitoring device 24 in Embodiment One as examples.

As shown in FIG. 6, when the first switch 25 is turned on and the second switch 26 is turned off, the gaseous tungsten powder 61 in the powder storage tank 21 runs along the outlet duct 23 and into the monitoring device 24, the monitoring device 24 would feed the monitored gaseous tungsten powder content per unit volume in the outlet duct 23 back to the alarm regulating device 62, the alarm regulating device 62 compares the received value of the gaseous tungsten powder content per unit volume with a preset range, when the value of gaseous tungsten powder content per unit volume exceeds the preset range, the alarm regulating device 62 issues an alert and controls the movable structure to move until the alarm is eliminated. For example, when the value of gaseous tungsten powder content per unit volume is less than the minimum value of the preset range, an alert is issued, and the piston in the powder storage tank 21 is controlled to move upward so as to decrease the volume of the powder storage tank 21. In the process of movement, if the alarm disappears, the piston is controlled to stop motion. The preset range used in the exemplary embodiment of the present disclosure could be set according to the pre-established relation database of one-to-one correspondence of the pressure to the gaseous tungsten powder content per unit volume as well as the pressure to the film thickness and also according to the production requirements.

For example, when the alarm disappears, it represents that the tungsten powder content is normal, then the second switch 26 can be turned on, and the first switch 25 is turned off, the device works normally. If the alarm has not been removed during the entire movement of the piston to the preset position, a shutdown check is required, and replacing the tungsten powder and cleaning the pipes are considered. The preset position provided in the powder storage tank 21 may be provided according to production requirements.

In practice, according to the gaseous tungsten powder content per unit volume in the outlet duct fed back by the monitoring device, the alarm level is classified into 1, 2, 3 and 4 levels. According to different levels, the bottom end face of the powder storage tank is adjusted so as to increase the tungsten powder content per unit volume, if the alarm continues, it is required to consider replacing the tungsten powder and cleaning the pipe.

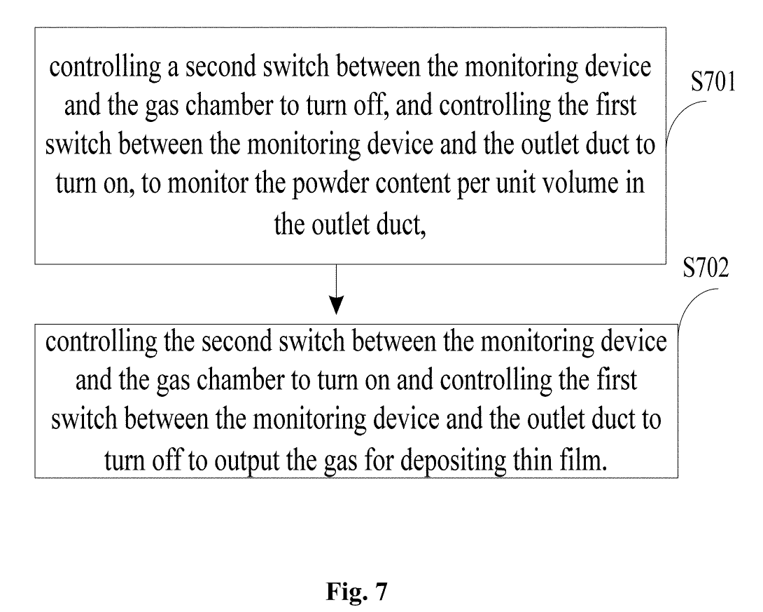

As shown in FIG. 7, an exemplary embodiment of the present disclosure also provides a method for using the apparatus, including steps below.

S701, controlling a second switch between the monitoring device and the gas chamber to turn off, and controlling the first switch between the monitoring device and the outlet duct to turn on, to monitor the powder content per unit volume in the outlet duct.

S702, controlling the second switch between the monitoring device and the gas chamber to turn on and controlling the first switch between the monitoring device and the outlet duct to turn off to output the gas for depositing thin film.

For example, the monitoring device in the exemplary embodiment of the present disclosure includes a powder collecting device, a spring and a pressure sensor. The pressure sensor is connected to the powder collecting device through the spring, and the arrangement of the monitoring device may refer to the exemplary Embodiment One of the present disclosure.

The monitoring of the powder content per unit volume in the outlet duct includes: collecting the gaseous matter in the outlet duct and solidifies the collected gaseous matter into solid matter by the powder collecting device.

When the gaseous matter is solidified into solid matter, the pressure sensor obtains a value of time-varying pressure converted to a digital signal by detecting the pressure of the spring, and obtains the powder content per unit volume in the outlet duct according to the pre-established correspondence between the pressure and the powder content per unit volume.

For example, the bottom end of the powder storage tank in the exemplary embodiment of the present disclosure is designed as a movable structure configured to adjust the volume of the powder storage tank. The apparatus of the exemplary embodiment of the present disclosure also includes an alarm regulating device coupled with the powder storage tank and the monitoring device.

In this exemplary embodiment of the present disclosure, after monitoring out the powder content per unit volume in the outlet duct, the alarm regulating device receives the powder content per unit volume in the outlet duct fed back by the monitoring device, compares the value of the powder content per unit volume with a preset range, and when the value of the powder content per unit volume exceeds the preset range, issues an alarm, and controls the movable structure to move until the alarm is eliminated.

The exemplary embodiments of the present disclosure provide an apparatus including a powder storage tank and a gas chamber, the powder storage tank is provided with an outlet duct in communication with the gas chamber. The apparatus also includes a monitoring device, a first switch and a second switch. The first switch is provided between the monitoring device and the outlet duct, and the second switch is provided between the monitoring device and the gas chamber. The monitoring device is disposed between the powder storage tank and the gas chamber while communicating with the outlet duct, and is configured to monitor the powder content per unit volume in the outlet duct when the second switch is turned off and the first switch is turned on. The exemplary embodiments of the present disclosure use the monitoring device to monitor the content and use status of powder, which, compared with the case in which the use status of tungsten powder can only be recorded by recording the running time of the apparatus and observing the light transmittance of the deposited tungsten powder film, the stability of the content of the output powder is enormously improved, and the film quality in the process of maintenance is maintained as well as the success rate of the maintenance is increased.

The described above are only exemplary embodiments of the present disclosure, and the present disclosure is not intended to limited thereto. For one of ordinary skill in the art, various modifications and alternations may be made without departing from the spirit and scope of embodiments of the present disclosure, and all of these modifications and alternations shall fall within the scope of the present disclosure.

The present application claims the priority to the Chinese patent application No. 201610004251.6 entitled “Apparatus and Method of Using the Same” filed at Jan. 4, 2016, the entirety of which is incorporated herein by way of reference.

1. An apparatus, comprising:
a powder storage tank;
a gas chamber, the powder storage tank being provided with an outlet duct connected with the gas chamber;
a monitoring device;
a first switch; and
a second switch;
wherein the first switch is provided between the monitoring device and the outlet duct, and the second switch is provided between the monitoring device and the gas chamber; and the monitoring device is provided between the powder storage tank and the gas chamber and communicates with the outlet duct, and is configured to monitor powder content per unit volume in the outlet duct when the second switch is turned off and the first switch is turned on.

2. The apparatus according to claim 1, wherein the monitoring device comprises a powder collecting device, a spring and a pressure sensor;
the powder collecting device being configured to collect the gaseous matter in the outlet duct and solidify the collected gaseous matter into a solid matter when the first switch is turned on and the second switch is turned off;
the pressure sensor being connected with the powder collecting device through the spring, and configured to obtain a value of time-varying pressure converted to a digital signals by detecting the pressure of the spring when the gaseous matter is solidified into solid matter, and to obtain the powder content per unit volume in the outlet duct according to pre-established correspondence between the pressure and the powder content per unit volume.

3. The apparatus according to claim 2, wherein the powder collecting device comprises a hollow cylindrical collector configured to collect solid matters and a temperature regulating device coupled with the hollow cylindrical collector,
the temperature regulating device being configured to cool down the hollow cylindrical collector when the first switch is turned on and the second switch is turned off, to allow the gaseous matter to be solidified into solid matter.

4. The apparatus according to claim 3, wherein the temperature regulating device is further configured to warm up the hollow cylindrical collector when the first switch is turned off and the second switch is turned on, to allow the solid matter collected in the hollow cylindrical collector to be sublimated to gaseous matter.

5. The apparatus according to claim 4, wherein the temperature regulating device is a container filled with water,
when the first switch is turned on and the second switch is turned off, the temperature of the water is set to be a first preset temperature at which the gaseous matter is solidified into solid matter; and
When the first switch is turned off and the second switch is turned on, the temperature of the water is set to be a second preset temperature at which the solid matter is sublimated to gaseous matter.

6. The apparatus according to claim 5, wherein the monitoring device is provided with a recovery pump therein which is configured to clean the monitoring device.

7. The apparatus according to claim 1, wherein the monitoring device comprises a cooling device, a sampling room and a particle concentration detector;
the cooling device being disposed proximate to the sampling room and configured to solidify the gaseous matter in the outlet duct into solid matter when the first switch is turned on and the second switch is turned off;
the sampling room being configured to collect the solid matter; and
the particle concentration detector being provided within the sampling room and configured to detect the concentration of the solid matter.

8. The apparatus according to claim 6, wherein the bottom end of the powder storage tank is provided as a movable structure configured to adjust the volume of the powder storage tank;
the apparatus further comprises an alarm regulating device coupled with the powder storage tank and the monitoring device, the alarm regulating device being configured to receive the powder content per unit volume in the outlet duct fed back by the monitoring device, compare the value of the powder content per unit volume with a preset range, when the value of the powder content per unit volume exceeds the preset range, issue an alarm and control movement of the movable structure until the alarm is eliminated.

9. The apparatus according to claim 8, wherein the movable structure is a piston.

10. The apparatus according to claim 9, wherein the outlet of the outlet duct connected with the powder storage tank has a trapezoidal cross-sectional shape.

11. The apparatus according to claim 10, wherein the powder storage tank is provided with an intake duct configured to introduce an inert gas, the inlet of the intake duct connected with the powder storage tank has a trapezoidal cross-sectional shape.

12. The apparatus according to claim 11, wherein the first switch is an electromagnetic valve; and the second switch is an electromagnetic valve.

13. A method of using the apparatus according to claim 1, comprising:
controlling a second switch between the monitoring device and the gas chamber to turn off, and controlling the first switch between the monitoring device and the outlet duct to turn on, to monitor the powder content per unit volume in the outlet duct; and
controlling the second switch between the monitoring device and the gas chamber to turn on and controlling the first switch between the monitoring device and the outlet duct to turn off to output the gas for depositing a thin film.

14. The method according to claim 13, wherein the monitoring device comprises a powder collecting device, a spring and a pressure sensor, the pressure sensor being connected with the powder collecting device through the spring;
the monitoring of the powder content per unit volume in the outlet duct comprises:
collecting the gaseous matter in the outlet duct by the powder collecting device and solidifying the collected gaseous matter into solid matter;
obtaining a value of time-varying pressure converted to a digital signals by detecting the pressure of the spring, and obtaining the powder content per unit volume in the outlet duct according to the pre-established correspondence between the pressure and the powder content per unit volume by the pressure sensor.

15. The method according to claim 14, wherein the bottom end of the powder storage tank is implemented as a movable structure configured to adjust the volume of the powder storage tank;
the method further comprises coupling an alarm regulating device with the powder storage tank and the monitoring device, and after monitoring out the powder content per unit volume in the outlet duct, the alarm regulating device receives the powder content per unit volume in the outlet duct fed back by the monitoring device, compares the value of the powder content per unit volume with a preset range, and when the value of the powder content per unit volume exceeds the preset range, issue an alarm and controlling the movement of the movable structure until the alarm is eliminated.

16. The apparatus according to claim 1, wherein the powder collecting device comprises a hollow cylindrical collector configured to collect solid matters and a temperature regulating device coupled with the hollow cylindrical collector, the temperature regulating device being configured to cool down the hollow cylindrical collector when the first switch is turned on and the second switch is turned off, to allow the gaseous matter to be solidified into solid matter.

17. The apparatus according to claim 3, wherein the temperature regulating device is a container filled with water,
when the first switch is turned on and the second switch is turned off, the temperature of the water is set to be a first preset temperature at which the gaseous matter is solidified into solid matter; and
when the first switch is turned off and the second switch is turned on, the temperature of the water is set to be a second preset temperature at which the solid matter is sublimated to gaseous matter.

18. The apparatus according to claim 17, wherein the monitoring device comprises a cooling device, a sampling room and a particle concentration detector;
the cooling device being disposed proximate to the sampling room and configured to solidify the gaseous matter in the outlet duct into solid matter when the first switch is turned on and the second switch is turned off;
the sampling room being configured to collect the solid matter; and
the particle concentration detector being provided within the sampling room and configured to detect the concentration of the solid matter.

19. The apparatus according to claim 18, wherein the monitoring device is provided with a recovery pump therein which is configured to clean the monitoring device.

20. The apparatus according to claim 7, wherein the bottom end of the powder storage tank is provided as a movable structure configured to adjust the volume of the powder storage tank;
the apparatus further comprises an alarm regulating device coupled with the powder storage tank and the monitoring device, the alarm regulating device being configured to receive the powder content per unit volume in the outlet duct fed back by the monitoring device, compare the value of the powder content per unit volume with a preset range, when the value of the powder content per unit volume exceeds the preset range, issue an alarm and control movement of the movable structure until the alarm is eliminated.
